(19) United States
(12) Patent Application Publication
(10) Pub. No.: US 2011/0026207 A1
(43) Pub. Date: Feb. 3, 2011

(54) PORTABLE ELECTRONIC DEVICE

(76) Inventors: Hideharu Takezawa, Nara (JP); Tomohiko Yokoyama, Osaka (JP); Kazuya Iwamoto, Osaka (JP); Taisuke Yamamoto, Nara (JP)

Correspondence Address: MCDERMOTT WILL & EMERY LLP, 600 13TH STREET, NW, WASHINGTON, DC, 20005-3096, US

(21) Appl. No.: 12/936,365

(22) PCT Filed: Sep. 18, 2009
(86) PCT No.: PCT/JP2009/004757

§ 371 Date: Oct. 4, 2010

(30) Foreign Application Priority Data
Sep. 22, 2008 (JP) 2008-242151

(51) Int. Cl. H05K 7/00

(52) U.S. Cl. 361/679.01

(57) ABSTRACT

A portable electronic device of the present invention includes a package, an electronic device body, a battery housing portion including a battery fitting portion for fitting a secondary battery therein, a foaming agent-containing layer provided on a surface of the battery housing portion, and a secondary battery to be fitted in the battery fitting portion. The foaming agent-containing layer is normally thin and, in the event of the battery generating heat, the layer turns into a thicker foamed layer which exhibits superior thermal insulation properties. Thus, it is possible to provide a portable electronic device having the degree of freedom in design for size and thickness reduction achieved at a high level, while offering high-level safety and reliability.

### TECHNICAL FIELD

The present invention relates to portable electronic devices. More specifically, the present invention relates to improvements to package structures for housing secondary batteries as power sources.

### BACKGROUND ART

For portable electronic devices, such as cell phones, personal digital assistants, notebook computers, camcorders, and handheld game machines, advanced functionality results in an increased number of heat-generating components mounted on a board. In use of the portable electronic device, heat dissipation from heat-generating components might cause the package surface to be locally heated to high temperature.

Patent Document 1 discloses a structure in which heat from heat-generating components housed in the package of a portable electronic device is advantageously diffused by a heat-conducting member with superior heat dissipation performance which is arranged around the heat-generating components. Examples of the heat-conducting member include metallic materials such as aluminum alloy, magnesium alloy, stainless steel, and plain steel.

Patent Document 2 discloses a flame-retardant resin composition which includes aromatic polycarbonate having a phosphorous flame retardant added thereto and is used as a material for packages and components of electronic devices.

Patent Document 3 discloses a resin composition containing a heat-absorbing material such as aluminum hydroxide or magnesium hydroxide. Aluminum hydroxide and magnesium hydroxide reduce combustion heat by an endothermic reaction. The endothermic reaction is a reaction in which water is released. The endothermic reaction exerts a flame retardant effect.

Patent Document 4 discloses a vacuum-insulated container for use in housing a battery module including a plurality of sodium-sulfur unit cells. The vacuum-insulated container includes a box-like container body with an opening at the top and a container top lid attached to the opening of the container body, and has a granulated fire-retardant material filling in the ceiling portion of the container top lid. Examples of the granulated fire-retardant material include filler sand, lightweight aggregate, pulverized glass, and foamed glass.

Patent Document 1: International Publication WO2008/062879 pamphlet

Patent Document 2: Japanese Patent Gazette No. 3682148

Patent Document 3: Specification of Japanese Patent No. 3408676

Patent Document 4: Japanese Laid-Open Patent Publication No. 2000-30739

### DISCLOSURE OF THE INVENTION

### Problem to be Solved by the Invention

It is assumed that secondary batteries generate heat, for example, when they are subjected to an extremely significant impact. Also, in the case of lithium ion secondary batteries, it is assumed that the amount of heat generated upon impact is considerable since they can store more energy, leading to an abrupt temperature rise.

To inhibit the surface of the portable electronic device from being heated to high temperature when the secondary battery generates heat, a heat-insulating layer is provided around the secondary battery. Since the lithium ion secondary battery is assumed to generate a larger amount of heat, the heat-insulating layer is required to be thick. However, increasing the thickness of the heat-insulating layer reduces the degree of freedom in design for size and thickness reduction of the portable electronic device.

An object of the present invention is to provide a portable electronic device with superior safety, including a foaming agent-containing layer which is thin when the battery generates no heat and turns into a thicker foamed layer with superior thermal insulation properties in the event of heat generation in the battery.

### Means for Solving the Problem

The present invention is directed to a portable electronic device having a secondary battery as a power source, comprising a package, an electronic device body housed in the package, a battery housing portion being a molding housed in the package, which has a battery fitting portion with a predetermined shape for fitting the secondary battery therein, and a foaming agent-containing layer provided on a surface of the battery housing portion on the side of which the secondary battery is fitted, the foaming agent-containing layer foaming by heating.

### EFFECT OF THE INVENTION

The portable electronic device of the present invention is provided with a foaming agent-containing layer which foams by heating, resulting in an increased degree of freedom in design for size and thickness reduction in normal state where the battery generates no heat. Also, when the battery generates heat, the foaming agent-containing layer foams to turn into a foamed layer exhibiting superior thermal insulation properties. Thus, the portable electronic device of the present invention is highly safe because an abrupt surface temperature rise is inhibited even in the event of heat generation in the battery.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIG. 1 is a top view schematically illustrating the appearance of a cell phone, which is a portable electronic device according to a first embodiment.

FIG. 2 is a cross-sectional view taken from line II-II of the cell phone shown in FIG. 1.

FIG. 3 is a perspective view schematically illustrating an electronic device body.

FIG. 4 is a perspective view schematically illustrating a battery housing portion.

FIG. 5 is a longitudinal sectional view schematically illustrating in cross section the shape of the battery housing portion having a secondary battery housed therein.

FIG. 6 is a longitudinal sectional view schematically illustrating the configuration of a cell phone, which is a portable electronic device according to a second embodiment.

FIG. 7 is a longitudinal sectional view schematically illustrating in cross section the shape of a battery housing portion having a secondary battery housed therein.

### DETAILED DESCRIPTION OF EMBODIMENTS

### First Embodiment

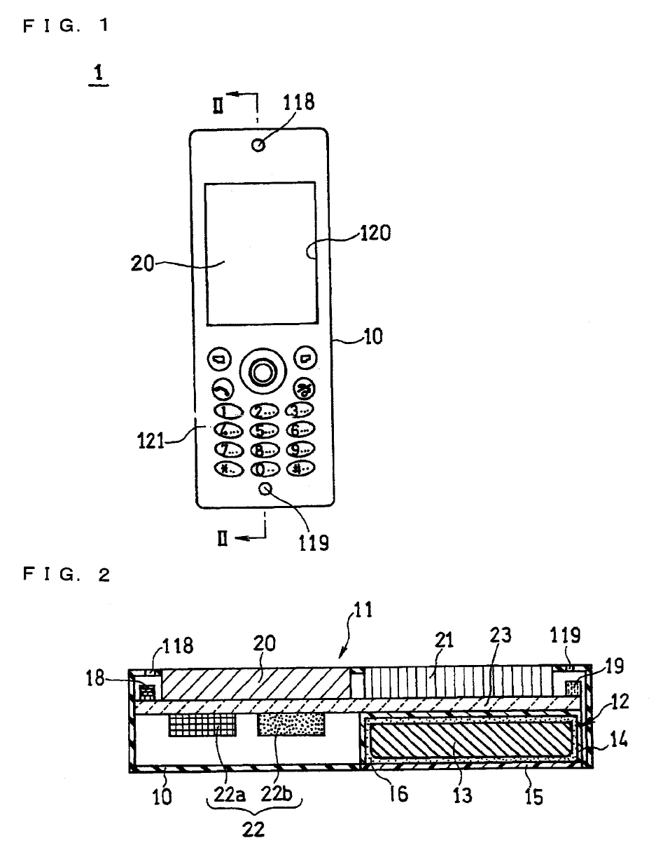

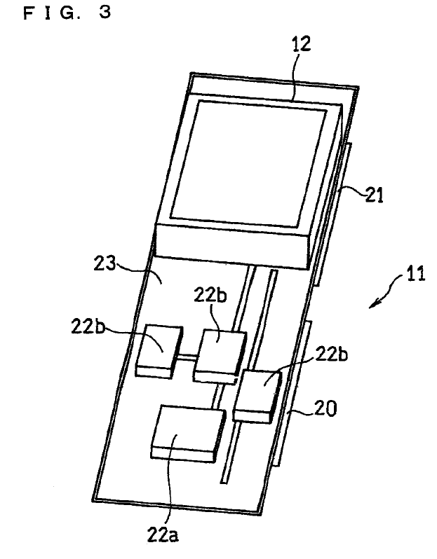

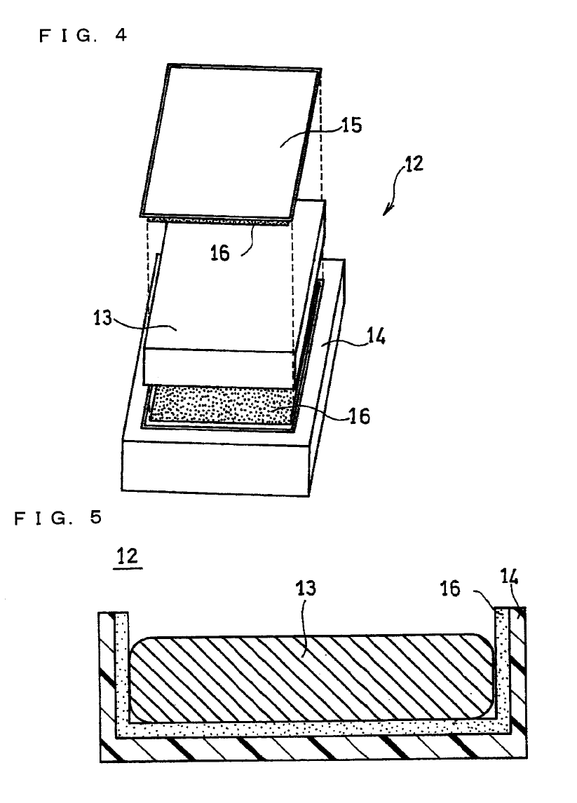

FIG. 1 is a top view schematically illustrating the appearance of a cell phone 1, which is a portable electronic device in a first embodiment of the present invention. FIG. 2 is a cross-sectional view taken from line II-II of the cell phone 1 shown in FIG. 1. FIG. 3 is a perspective view including an electronic device body 11 and a battery housing portion 12. FIG. 4 is a perspective view of the battery housing portion 12, illustrating the secondary battery 13 being housed. FIG. 5 is a longitudinal sectional view schematically illustrating in cross section the shape of the battery housing portion 12 having the secondary battery 13 housed therein.

First, the configuration of the cell phone 1 will be described.

The cell phone 1 includes a package 10, the electronic device body 11 housed in the package 10, the battery housing portion 12, and the secondary battery 13 housed in the battery housing portion 12, as shown in FIGS. 1 and 2. The electronic device body 11 includes a speaker 18, a microphone 19, an image display portion 20, an input operation portion 21, a circuit portion 22, and a circuit board 23.

The speaker 18, the microphone 19, the image display portion 20, the input operation portion 21, and the circuit portion 22 are mounted on the circuit board 23 having predetermined circuitry formed thereon. The battery housing portion 12 includes positive and negative terminals by which the battery housing portion 12 is mounted at a predetermined position on the circuitry of the circuit board.

As shown in FIG. 2, the speaker 18 is disposed so as to face an earpiece hole 118 provided at a predetermined position in the package 10. Also, the microphone 19 is disposed so as to face a mouthpiece hole 119 provided at a predetermined position in the package 10. The image display portion 20 is disposed and fitted in a display hole 120 provided in the package 10 so that display can be recognized from outside.

The input operation portion 21 is disposed and fitted in an input portion 121 which is a face including a combination of input buttons provided in the package 10 such that the operator can input information. Note that the circuit board 23 may have a card connector and/or a small camera device additionally mounted on its surface as necessary.

The speaker 18 emits an incoming call notification sound and also outputs incoming speech. Outgoing speech is inputted via the microphone 19. The image display portion 20 displays images, characters, graphics, or video. As the image display portion 20, a liquid crystal monitor or suchlike can be used. The input operation portion 21 receives operations inputted through the input portion 121. In the case where the image display portion 20 is a touch panel, the image display portion 20 doubles as the input operation portion 21.

The circuit portion 22 includes a circuit control portion 22a and a storage portion 22b. The circuit control portion 22a executes various operational controls in accordance with input information provided by the operator via the input operation portion 21. The storage portion 22b stores, for example, the input information provided by the operator. As the circuit control portion 22a, a plurality of IC chips or a central processing unit (CPU) is used. As the storage portion 22b, memory such as RAM or ROM is used.

The electronic device body 11 is driven by power supplied by the secondary battery 13.

The operator performs input operation via the input operation portion 21 to transmit a command signal to the circuit control portion 22a. Then, the transmitted command signal triggers a predetermined operation. Also, the input information is stored to the storage portion 22b as necessary.

In addition, the operator speaks into the microphone 19. The produced speech is converted into a radio signal by a circuit inside the circuit portion 22, which is transmitted to another receiver. Furthermore, a radio signal outputted by another receiver is received by an antenna circuit. The received radio signal is converted into a speech signal by a circuit inside the circuit portion 22, which is outputted by the speaker 18.

Next, the package 10 included in the cell phone 1 will be described. The package 10 has housed therein the electronic device body 11 and the battery housing portion 12. The package 10 is made from, for example, a metallic material or a resin material.

Next, the battery housing portion 12 included in the cell phone 1 will be described in detail.

The battery housing portion 12 includes a battery fitting portion 14 for fitting the secondary battery 13 therein and a lid portion 15 for covering the secondary battery 13 fitted in the battery fitting portion 14, as shown in FIG. 2.

The battery fitting portion 14 is a recessed member having an internal space corresponding to the shape of the secondary battery 13. An opening of the recess is disposed so as to be directed outward from the package 10 in order to allow battery replacement. The battery fitting portion 14 is provided with a positive terminal portion (not shown) which is brought into contact with the positive terminal (not shown) of the secondary battery 13 to be fitted and a negative terminal portion (not shown) which is brought into contact with the negative terminal (not shown) of the secondary battery 13.

The lid portion 15 is a member detachably provided to the battery fitting portion 14 of the package 10. The lid portion 15 is attached so as to cover the secondary battery 13 fitted in the recessed portion, thereby occupying the opening of the recessed portion. The secondary battery 13 is supported by the recessed portion having the secondary battery 13 fitted therein.

The secondary battery 13 to be housed in the battery housing portion 12 may be a unit cell or may be in the form of a battery pack including unit cells combined in series or parallel. The surface of the unit cell may be covered with, for example, a resin label. Preferably used as the unit cells are high-capacity and high-energy density lithium ion secondary batteries, which are conventionally used in portable electronic devices and can be reduced in size.

Among the lithium ion secondary batteries, those containing a silicon- or tin-based active material as a negative electrode active material are preferable. The silicon- and tin-based active materials can achieve higher capacity and energy density for the lithium ion secondary battery. The silicon-based active material is not limited to any specific material so long as it is a silicon-containing active material, but silicon, silicon oxide, silicon alloy, or the like is preferable. The tin-based active material is not limited to any specific material so long as it is a tin-containing active material, but tin, tin oxide, tin alloy, or the like is preferable. Among them, the silicon-based active material is particularly preferable.

The battery fitting portion 14 and the lid portion 15 are preferably made from a resin material or a metallic material. Preferably used as the resin material is a flame-retardant resin composition which includes a matrix resin, such as polycarbonate, polypropylene or polyethylene terephthalate, having a flame retardant added thereto. The flame-retardant resin composition preferably has a flame-retardant rating of V-0 or higher in the UL-94 burn test. Preferably used as the metallic material without limitation is, for example, stainless steel, magnesium alloy, or aluminum alloy.

Furthermore, a foaming agent-containing layer 16 is provided on a surface of the battery fitting portion 14 that faces the secondary battery 13 (hereinafter, also referred to as a “battery fitting-side surface”) and on a surface of the lid portion 15 that faces the secondary battery 13 (hereinafter, a “facing-side surface”), as shown in FIGS. 2 and 5. In this manner, the foaming agent-containing layer 16 is formed on the surface of the battery housing portion 12 on the side of which the secondary battery 13 is housed.

In such a configuration, the secondary battery 13 housed in the battery housing portion 12 is surrounded by the foaming agent-containing layer 16. The foaming agent-containing layer 16 can be formed in such a thickness so as not to lessen the degree of freedom in design for size and thickness reduction of the cell phone 1. Also, the foaming agent-containing layer 16 contains a foaming agent that has not yet foamed, and the foaming agent is foamed by heat generated from the secondary battery 13, resulting in a thicker, highly insulating foamed layer.

In this manner, forming the foaming agent-containing layer 16 around the secondary battery 13 results in no reduction in the degree of freedom in design for size and thickness reduction of the cell phone 1 when no heat is generated by the secondary battery 13. On the other hand, when heat is generated by the secondary battery 13 being subjected to a significant impact or suchlike, the foaming agent-containing layer 16 turns into a foamed layer, inhibiting the surface of the cell phone 1 from being heated to high temperature. Thus, it is possible to provide the cell phone 1 with a high degree of freedom in design for size and thickness reduction, along with superior safety and reliability.

The foaming agent-containing layer 16 is mainly composed of alkali metal silicate. Alkali metal silicate contains a relatively high amount of water of crystallization, and foams by releasing water of crystallization upon heating to about 110° C. or higher. Upon foaming of alkali metal silicate, the foaming agent-containing layer 16 has a number of foamed cells generated therein, resulting in a thicker, foamed layer. The foamed layer exhibits high thermal insulation properties.

Also, alkali metal silicate cools its surroundings by latent heat upon releasing water of crystallization. In addition, alkali metal silicate is a nonflammable inorganic material having neither an ignition point nor a flash point. Accordingly, alkali metal silicate is an advantageous material for enhancing the safety and reliability of the cell phone 1.

As alkali metal silicate, at least one silicate selected from Na-, K-, and Li-silicates can preferably be used. Among these alkali metal silicates, from the viewpoint of enhancing the binding strength of the foaming agent-containing layer 16, K-silicate is preferable to Li-silicate, and Na-silicate is preferable to K-silicate. Also, from the viewpoint of enhancing water resistance of the foaming agent-containing layer 16, K-silicate is preferable to Na-silicate, and Li-silicate is preferable to K-silicate.

Accordingly, Na-, K-, and Li-silicates may be suitably selected and used in accordance with characteristics required for the foaming agent-containing layer 16. In this case, one silicate may be used alone or two or more silicates may be used in combination.

The foaming agent-containing layer 16 preferably contains at least one agent along with the alkali metal silicate, the agent being selected from a foam booster and a filler.

A preferable foam booster to be used generates gas at high temperature, and a more preferable foam booster to be used generates gas at a temperature higher than a temperature at which alkali metal silicate foams by releasing water of crystallization. Using such a foam booster promotes foaming of alkali metal silicate and increases the number of foamed cells in a foamed layer to be generated, thereby increasing the thickness of the foamed layer. As a result, thermal insulation properties of the foamed layer are further enhanced.

Specific examples of such a foam booster include aluminum hydroxide, calcium hydroxide, magnesium hydroxide, alum, sodium sulfate, calcium carbonate, magnesium carbonate, and barium carbonate. One foam booster may be used alone or two or more foam boosters may be used in combination.

Among these foam boosters, aluminum hydroxide and magnesium hydroxide are preferable. It is particularly preferable to use aluminum hydroxide and magnesium hydroxide together with Na-silicate. Na-silicate foams by releasing water of crystallization in the temperature range from approximately 130 to 150° C. On the other hand, aluminum hydroxide releases gas in the temperature range from about 200 to 300° C. and magnesium hydroxide releases gas in the temperature range from about 400° C. or higher.

Accordingly, when aluminum hydroxide and magnesium hydroxide are used together with Na-silicate, aluminum hydroxide and magnesium hydroxide release gas even at a temperature higher than a temperature at which Na-silicate releases water of crystallization. Therefore, foaming continues in the temperature range from approximately 130° C. to more than 400° C. As a result, thermal insulation properties of the foamed layer are further enhanced with increase in temperature, and therefore the surface temperature of the cell phone 1 can be inhibited from rising even if the temperature of the secondary battery 13 rises.

The content of the foam booster in the foaming agent-containing layer 16 is preferably 5 to 95 parts by mass, more preferably 20 to 80 parts by mass, per 100 parts by mass of alkali metal silicate. When the content of the foam booster is excessively low, the foam booster tends to be less effective. When the content of the foam booster is excessively high, the foaming agent-containing layer 16 tends to have a lower binding strength. As a result, the foaming agent-containing layer 16 tends to partially flake, for example.

A preferable filler to be used has the effect of maintaining the shape of the foaming agent-containing layer 16. Specific examples of such a filler include aluminum silicate, sodium silicofluoride, bentonite, montmorillonite, kaolinite, mullite, diatomaceous earth, alumina, silica, mica, titanium oxide, vermiculite, pearlite, maglite, sepiolite, talc, calcium silicate, magnesium silicate, calcium sulfate, and cement. One filler may be used alone or two or more fillers may be used in combination.

The content of the filler in the foaming agent-containing layer 16 is preferably 5 to 70 parts by mass, more preferably 10 to 50 parts by mass, per 100 parts by mass of alkali metal silicate. When the content of the filler is excessively low, the foaming agent-containing layer 16 tends to have a locally uneven thickness upon foaming, resulting in reduced thermal insulation properties of the resultant foamed layer. When the content of the filler is excessively high, the foamed layer tends to be formed with insufficient thermal insulation properties.

For example, the foaming agent-containing layer 16 can be obtained by forming a coating film by applying to the surface on which to form the foaming agent-containing layer 16, a foaming agent-containing layer formation composition containing alkali metal silicate, and as necessary, at least one selected from a foam booster and a filler.

For example, the foaming agent-containing layer formation composition can be prepared by dissolving or dispersing alkali metal silicate in an organic solvent or water. In this case, the at least one agent selected from a foam booster and a filler may be dissolved or dispersed in the organic solvent or water, along with alkali metal silicate. The foaming agent-containing layer 16 is then obtained by forming a coating film through application of the foaming agent-containing layer formation composition thus prepared to the battery fitting-side surface of the battery housing portion 12 and the facing-side surface of the lid portion 15.

For application of the foaming agent-containing layer formation composition, any conventionally known application methods can be employed without limitation, including methods such as immersion application, roller application, spray application, and doctor blade application. After application, the coating film that is to serve as the foaming agent-containing layer 16 is formed by, for example, removing the solvent by drying.

Note that in the present embodiment, the foaming agent-containing layer 16 is provided on both the battery fitting-side surface of the battery fitting portion 14 and the facing-side surface of the lid portion 15 but the foaming agent-containing layer 16 may be provided on only one of them.

### Second Embodiment

Next, a cell phone of a second embodiment will be described. The cell phone of the second embodiment is configured in the same manner as the cell phone 1 of the first embodiment except that a block layer is provided together with the foaming agent-containing layer. To avoid overlapping descriptions, descriptions other than detailed descriptions of the block layer structure will be omitted.

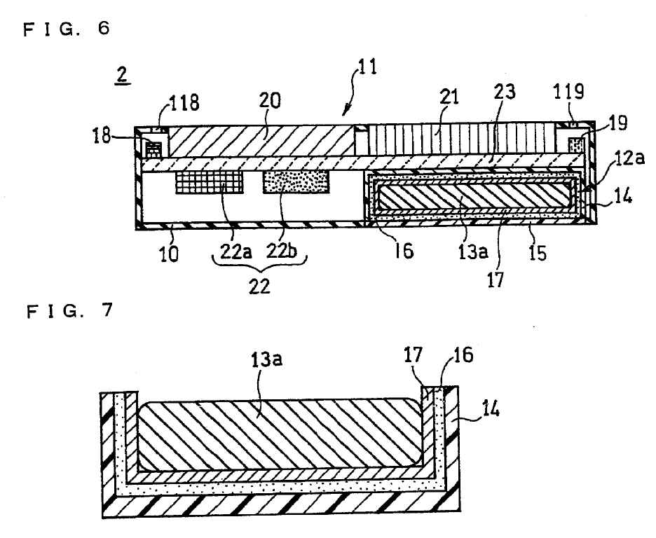

FIG. 6 is a longitudinal sectional view schematically illustrating the configuration of a cell phone 2, which is a portable electronic device of the second embodiment. FIG. 7 is a longitudinal sectional view schematically illustrating in cross section the shape of a battery housing portion 12a having a secondary battery 13a housed therein. The battery housing portion 12a of the cell phone 2 in the second embodiment includes a block layer 17 as described below, which is formed on the surface of the foaming agent-containing layer 16 formed in the battery housing portion 12 of the cell phone 1 in the first embodiment.

Specifically, as shown in FIGS. 6 and 7, the foaming agent-containing layer 16 is formed on both the battery fitting-side surface of the battery fitting portion 14 and the facing-side surface of the lid portion 15, and the block layer 17 is formed on the surface of the foaming agent-containing layer 16 for inhibiting discharge of the content from the secondary battery 13a in an overheated state. In this manner, the foaming agent-containing layer 16 and the block layer 17 are sequentially formed on the surface of the battery housing portion 12a on the side of which the secondary battery 13a is housed.

The secondary battery 13a is a lithium ion secondary battery including at least one negative electrode active material selected from a silicon-based active material and a tin-based active material. The temperature of heat generated by such a lithium ion secondary battery is assumed to be higher than the temperature of heat generated by conventional lithium ion secondary batteries including graphite as a negative electrode active material. Also, for example, if such a lithium ion secondary battery is subjected to an extremely significant impact, heat is generated, and a highly reactive alkali salt such as lithium orthosilicater might be produced and then caused to melt. A melt of alkali salt is assumed to leak out of the battery.

On the other hand, in the configuration of the present embodiment, the secondary battery 13a housed in the battery housing portion 12a is surrounded by the block layer 17 which is in turn surrounded by the foaming agent-containing layer 16. In this manner, by forming the block layer 17 inside the foaming agent-containing layer 16, the foaming agent-containing layer 16 is prevented from being in direct contact with a high-temperature melt of alkali salt flowing out from the secondary battery 13a in an overheated state due to a significant impact being applied thereto. Thus, it is possible to inhibit functional loss of the foaming agent-containing layer 16 due to contact with a melt of alkali salt.

As a result, a melt of alkali salt leaking from the secondary battery 13a can be reliably prevented from flowing outside the cell phone 2. Also, it is possible to inhibit heat generated by the secondary battery 13a from being locally conducted to the surface of the cell phone 2. Thus, the surface of the cell phone 2 can be inhibited from being locally heated to high temperature. Moreover, the package 10 included in the cell phone 2 can be inhibited from being damaged by heat.

Accordingly, to sufficiently exert the effect of the foaming agent-containing layer 16, the block layer 17 is preferably formed inside the foaming agent-containing layer 16.

Note that the configuration of the present embodiment is also useful for conventional lithium ion secondary batteries including a carbon material such as graphite as a negative electrode active material. If such a conventional lithium ion secondary battery generates heat, it is assumed that a temperature rise and a flame might be caused. On the other hand, by providing the block layer 17 around the secondary battery 13a and the foaming agent-containing layer 16 around the block layer 17, the block layer 17 can prevent the foaming agent-containing layer 16 from being in contact with a flame. This allows the foamed layer produced from the foaming agent-containing layer 16 to exert sufficient thermal insulation properties. As a result, it is possible to inhibit the surface of the cell phone 2 from being locally heated to high temperature.

The block layer 17 is made from a metallic material resistant to a melt of alkali salt. Among all alkali salt melts, the metallic material is preferably resistant to a melt of lithium orthosilicater at a liquid temperature of 1450° C. The “resistant” as used herein is intended to mean that 50 μm-thick metallic foil made of a metallic material is not caused to melt by contact with a melt of lithium orthosilicater at a liquid temperature of 1450° C. More preferably, the “resistant” here is intended to mean 50 μm-thick metallic foil made of a metallic material is not caused to melt to become perforated by contact with a melt of lithium orthosilicater at a liquid temperature of 1450° C.

A specific example of such a metallic material is at least one metal or metal nitride selected from the group consisting of iron, vanadium, niobium, molybdenum, tantalum, tungsten, titanium nitride, and stainless steel.

Although the thickness of the block layer 17 is not specifically limited, it is preferably 20 μm or more, more preferably 30 μm to 300 μm. When the block layer 17 is excessively thin, the block layer 17 might have a hole made by contact with a melt of alkali salt. Also, when the block layer 17 is excessively thick, the degree of freedom in design for size reduction of the cell phone 2 might be reduced.

To form the block layer 17, a molding made of a metallic material resistant to a melt of alkali salt is laid on the surface of the foaming agent-containing layer 16. Also, the block layer 17 may be formed not only by simply laying the molding but also by bonding the molding onto the surface of the foaming agent-containing layer 16. Furthermore, instead of bonding, the molding may be fixed by catches previously provided on the battery fitting-side surface of the battery fitting portion 14 and the facing-side surface of the lid portion 15 for fixing the molding. Such a catch is provided so as to project from the surface of the foaming agent-containing layer 16.

Examples of the molding include a foil or plate made of a metallic material resistant to a melt of alkali salt and moldings obtained by drawing or welding such a metallic material resistant to a melt of alkali salt.

Note that in the present embodiment, the foaming agent-containing layer 16 and the block layer 17 are provided on both the battery fitting-side surface of the battery fitting portion 14 and the facing-side surface of the lid portion 15 but the foaming agent-containing layer 16 and the block layer 17 may be provided on only one of them.

The first and second embodiments have been described with respect to the cell phone with a battery housing portion having a battery fitting portion and a lid portion, but this is not restrictive. The configuration of the present invention is applicable to, for example, cell phones having a battery housing portion detachably provided to the cell phone package and cell phones incorporating secondary batteries.

While the portable electronic device of the present invention has been described in detail by way of exemplary cell phones of the first and second embodiments, the present invention is naturally applicable to portable electronic devices other than the cell phones. Specifically, the present invention can be applicable to, for example, PDAs, game machines, digital still cameras (DSCs), portable music devices, and portable electronic devices, such as notebook computers and portable camcorders, which have a battery pack including a combination of secondary batteries as a power source. Moreover, the technical features of the present invention are also applicable to exterior materials for large secondary batteries for use as power sources of electric vehicles, for example.

### EXAMPLES

Hereinafter, the present invention will be described in further detail based on examples, but the present invention is not to be construed as being limited by the following examples and suitable changes can be made without departing from the scope of the invention.

### Example 1

A foaming agent-containing layer formation composition, which is an aqueous solution of sodium silicate, was prepared by dissolving 80 parts by mass of sodium silicate (product name: JIS No. 3 sodium silicate, manufactured by Osaka Keisou) in 20 parts by mass of water. The foaming agent-containing layer formation composition was applied to one surface of a polycarbonate resin plate (0.9 mm thick, 10 mm×100 mm) having a rating of V-0 according to the UL 94 flammability standard and air-dried overnight, forming a foaming agent-containing layer having a film thickness of 0.2 mm.

A ceramic heater (product name: MS-M5, manufactured by Sakaguchi E.H VOC Corp.) was disposed on the surface of the foaming agent-containing layer, and housed in the package of the cell phone. A voltage of 6V was applied to the ceramic heater, and the temperature of the ceramic heater was set to 700° C. The surface temperature of the resin plate and the temperature of the ceramic heater were measured with a thermocouple.

When the temperature of the ceramic heater reached 115° C., sodium silicate in the foaming agent-containing layer foamed and the foaming agent-containing layer started to expand. When the temperature of the ceramic heater reached 700° C., the foaming agent-containing layer turned into a foamed layer, the thickness of which was 12 mm. At this time, the temperature of the surface of the resin plate that had no foaming agent-containing layer formed thereon was 90° C., and neither sparks nor deformation of the resin plate were observed.

The results clearly show that a 0.2 mm-thick foaming agent-containing layer turns into a 12 mm-thick foamed layer by heating and the foamed layer exhibits sufficient thermal insulation properties.

### Comparative Example 1

A test was carried out in the same manner as in Example 1 except that the foaming agent-containing layer is not formed on either surface of the resin plate. As a result, when the temperature of the ceramic heater exceeded 150° C., the resin plate started to become soft, and then the resin plate was significantly deformed.

### Example 2

A foaming agent-containing layer formation composition was prepared by mixing 10 parts by mass of sodium silicate (JIS No. 3 silicate soda) with 90 parts by mass of a commercially available inorganic formable heat-insulating composition (product name: ACCERA COAT F, which contains silica as a filler, manufactured by ACCESS Co. Ltd.). This composition included 30 parts by mass of silica per 100 parts by mass of sodium silicate. The composition was used to form a 0.5 mm-thick foaming agent-containing layer on one surface of a polycarbonate resin plate, as in Example 1.

A test was carried out in the same manner as in Example 1, using the polycarbonate resin plate having the 0.5 mm-thick foaming agent-containing layer formed thereon. When the temperature of the ceramic heater reached about 130° C., sodium silicate in the foaming agent-containing layer foamed and the foaming agent-containing layer started to expand. When the temperature of the ceramic heater reached 700° C., a 1.8 mm-thick foamed layer was produced. At this time, the temperature of the surface of the resin plate that had no foaming agent-containing layer formed thereon was 250° C., and no significant deformation of the resin plate was observed.

The results clearly show that a 0.5 mm-thick foaming agent-containing layer turns into a 1.8 mm-thick foamed layer by heating, and the foamed layer exhibits sufficient thermal insulation properties.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

### INDUSTRIAL APPLICABILITY

The portable electronic device of the present invention is advantageous in that, the event of heat generation in a secondary battery causing the content therein to melt and a melt to leak thereout, an abrupt surface temperature rise and discharge of the melt from the portable electronic device are inhibited, and it can be used in the same applications as conventional portable electronic devices.

Also, a foaming agent-containing layer in the portable electronic device of the present invention is applicable to exterior materials for enhancing the safety of large-sized secondary batteries for use as drive sources of electric vehicles or suchlike.

1. A portable electronic device having a secondary battery as a power source, comprising:
a package, an electronic device body housed in the package, a battery housing portion being a molding housed in the package, which has a battery fitting portion with a predetermined shape for fitting the secondary battery therein, and a foaming agent-containing layer provided on a surface of the battery housing portion on the side of which the secondary battery is fitted, the foaming agent-containing layer foaming by heating.

2. The portable electronic device according to claim 1, further comprising a block layer provided on a surface of the foaming agent-containing layer for inhibiting discharge of the content from the secondary battery in an overheated state.

3. The portable electronic device according to claim 1, wherein the secondary battery is a lithium ion secondary battery which includes as a negative electrode active material at least one selected from the group consisting of a silicon-based active material and a tin-based active material.

4. The portable electronic device according to claim 1, wherein the foaming agent-containing layer includes alkali metal silicate as a foaming agent.

5. The portable electronic device according to claim 4, wherein the foaming agent-containing layer further includes at least one selected from a foam booster and a filler.

6. The portable electronic device according to claim 2, wherein the block layer is made of a metallic material resistant to a melt of alkali salt including silicon or tin.

7. The portable electronic device according to claim 6, wherein the metallic material is in the form of 50 μm-thick metallic foil resistant to melting by contact with a melt of lithium orthosilicater at a liquid temperature of 1450° C.

8. The portable electronic device according to claim 7, wherein the metallic material includes at least one metal or metal nitride selected from the group consisting of iron, vanadium, niobium, molybdenum, tantalum, tungsten, titanium nitride, and stainless steel.

9. The portable electronic device according to claim 1, wherein the secondary battery is in the form of a battery pack including a combination of unit cells.
